(19) United States
(12) Patent Application Publication
(10) Pub. No.: US 2008/0095292 A1
(43) Pub. Date: Apr. 24, 2008

(54) APPARATUS AND METHOD FOR CLOCK PHASE ALIGNMENT BETWEEN ACTIVE AND STANDBY CLOCK CARDS AND CLOCK CARD

(75) Inventor: Qing ZHANG, Shenzhen (CN)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: HUAWEI TECHNOLOGIES CO., LTD., Shenzhen (CN)

(21) Appl. No.: 11/963,052

(22) Filed: Dec. 21, 2007

Related U.S. Application Data
(63) Continuation of application No. PCT/CN2006/001474, filed on Jun. 27, 2006.

(30) Foreign Application Priority Data
Jun. 27, 2005 (CN) 200510079954.7

(51) Int. Cl. H03D 3/24

(52) U.S. Cl. 375/373

(57) ABSTRACT

The present invention discloses an apparatus and a method for clock phase alignment between active and standby clock cards. The apparatus includes: a Direct Digital Synthesizer (DDS) adapted for adjusting a clock phase of a clock card; a phase detection module adapted for detecting a phase difference between a clock of the clock card and that of a counterpart clock card; and a CPU adapted for calculating a value for the phase register within the DDS according to the detected phase difference. The method includes: if the clock card is in standby state, detecting a phase difference between a clock of the clock card and that of the counterpart clock card; and adjusting, by the DDS, a phase of the clock of the clock card to be aligned to that of the counterpart clock card, according to the detected phase difference. A clock card is further disclosed.

### CROSS-REFERENCES TO RELATED APPLICATIONS

The present application is a continuation of PCT Application No. PCT/CN2006/001474, filed on Jun. 27, 2006, which claims a priority to Chinese Patent Application No. 200510079954.7, filed on Jun. 27, 2005. All of these applications are incorporated herein by reference for all purposes.

### FIELD OF THE INVENTION

The present invention relates to a clock application technique in a communication device, especially to an apparatus and a method for clock phase alignment between active and standby clock cards, and a clock card.

### BACKGROUND OF THE INVENTION

A key part of a communication device is a clock, and various performances of the clock have an effect on performance of a card, and further have an effect on the entire system. Therefore, it is very important for a communication device to ensure accuracy and stability of various performances of a clock in the communication device. As a result, each of communication organizations, countries and operators performs rigorous testing on various performances of a clock in a communication device before putting the communication device into a network. Performance indexes of the clock mainly include a frequency and a phase, generally, performances for measuring these indexes include long term stability, long term accuracy, a maintenance capability, phase transient, phase discontinuity, etc.

Typically, a communication device has two clock cards, i.e., an active clock card and a standby clock card, which backup each other. The active clock card provides a system clock, and the standby clock card functions as a backup. When a switchover between the active and standby clock cards is carried out, there occurs between the active and standby clocks the phase transient and the phase discontinuity, which are two indexes very important to the system. For the purpose of reducing phase transient and maintaining phase continuity during a switchover between active and standby clock cards, the active and standby clock cards should be kept consistent in phase and frequency during the switchover, and hence be kept consistent in phase and frequency during normal operation. In these two indexes, i.e., the frequency and the phase, of the active and standby clock cards, the phase is a key technique affecting the performance of the switchover between the active and standby clock cards. With the increase in communication rate, the communication device has a higher requirement of phase accuracy.

With reference to FIG. 1, a schematic diagram illustrating configuration of a clock card in the prior art is shown, including: a reference source detection and selection module 101 for selecting a clock reference source, a phase locked module 102 for performing phase lock on the selected clock reference source, a frequency multiplier 103, a frequency divider 104, an output control module 105, an active and standby states control module 106, a CPU 107 and a communication module 108 for communicating with a main control card of the device. Here, for keeping the phase and the frequency of the active clock card consistent with those of the standby clock card, a method for output phase alignment is employed, which method includes that: a signal subjected to phase lock by the phase locked module 102 is outputted to the frequency multiplier 103 which multiplies the signal to a higher frequency, and then the signal is subjected to frequency division with counter by the frequency divider 104; depending on states (i.e., an active state or an standby state) of the clock card and the counterpart clock card, if the clock card is in standby state, the active and standby states control module 106 aligns the phase of the standby clock card to that of the active clock card through nulling/resetting the counter of the frequency divider 104; if the clock card is in active state, the active and standby states control module 106 controls the output control module 105 to output a clock signal.

However, in this method, the output signal needs undergo multiple stages of frequency multiplication/frequency division, as a result, phase noise is increased, so that jitter of the output signal is increased and signal quality is decreased; lots of logic resources are occupied, and a high speed is required for logic circuits; and the accuracy of phase alignment is relatively low, for example, the accuracy of phase alignment is 10.0 ns in the case of a counting clock having a high frequency of 100 MHz.

### SUMMARY OF THE INVENTION

In view of above disadvantages in the prior art, an object of the present invention is to provide an apparatus and a method for clock phase alignment between active and standby clock cards and a clock card, thereby achieving a higher accuracy in clock phase alignment between the active and standby clock cards.

To achieve the object above, an apparatus for clock phase alignment between active and standby clock cards is provided in the invention, the apparatus includes:

a Direct Digital Synthesizer (DDS) adapted for adjusting the phase of a clock of the clock card according to a value in a phase register within the Direct Digital Synthesizer;

a phase detection module adapted for detecting a phase difference between the phase adjusted clock of the clock card and an output clock of a counterpart clock card; and

a Central Processing Unit adapted for calculating a value for the phase register within the Direct Digital Synthesizer according to the phase difference detected by the phase detection module, and sending the value to the Direct Digital Synthesizer.

The apparatus further includes a phase locked module adapted for phase lock adjustment according to a reference clock of the clock card, and for outputting the phase locked clock to the Direct Digital Synthesizer.

The Direct Digital Synthesizer includes a phase register, a phase-amplitude converter and a digital-to-analog converter.

The Central Processing Unit is adapted to write into the phase register the calculated value for the phase register within the Direct Digital Synthesizer.

The phase register is adapted to generate a phase parameter according to the calculated value for the phase register and the received phase locked clock, and sends the phase parameter to the phase-amplitude converter.

The phase-amplitude converter is adapted to generate an amplitude parameter through conversion, and sends the amplitude parameter to the digital-to-analog converter; the digital-to-analog converter is adapted to generate a phase adjusted clock output according to the amplitude parameter and the received phase locked clock.

The Central Processing Unit is connected to the Direct Digital Synthesizer via a data bus and an address bus.

A method for clock phase alignment between active and standby clock cards is provided in the invention, the method includes:

if the clock card is in standby state, the steps performed includes:

A. detecting a phase difference between a clock of the clock card and an output clock of a counterpart clock card; and

B. adjusting, by a Direct Digital Synthesizer, the phase of the clock of the clock card to be aligned to the phase of the output clock of the counterpart clock card, according to the detected phase difference.

The step B may includes:

B1. calculating a value for a phase register of the Direct Digital Synthesizer according to the detected phase difference, and sending the value to the Direct Digital Synthesizer; and

B2. adjusting, by the Direct Digital Synthesizer, the phase of the clock of the clock card to be aligned to the phase of the output clock of the counterpart clock card, according to the value in the phase register.

At step A, whether the clock of the clock card leads or lags the output clock of the counterpart clock card is detected.

At step B1, a direction of phase adjustment is determined according to a detection result (i.e., a phase lead or a phase lag) from the step A, and the value in the phase register within the Direct Digital Synthesizer is determined as the original value in the phase register plus or minus a predefined step size.

The method may further include: determining whether further phase adjustment is needed; if the further phase adjustment is needed, returning to the step A; otherwise, ending the adjustment.

An approach of determining whether further phase adjustment is needed may include:

recording times for performing forward phase adjustment or backward phase adjustment; if a ratio of the times for one of the forward phase adjustment and the backward phase adjustment to the times for the other of the forward phase adjustment and the backward phase adjustment is approximately 50%, for example, the ratio is between 43% and 67%, then no further phase adjustment is needed.

The step B1 may further include that:

when a ratio of the times for one of the forward phase adjustment and the backward phase adjustment to the times for the other of the forward phase adjustment and the backward phase adjustment is higher than a predefined value, the step size for the one of the forward phase adjustment and the backward phase adjustment is adjusted to be integral times of the predefined step size.

The phase difference between the clock of the clock card and the output clock of the counterpart clock card may be detected through a phase detection module, which outputs a high level if the clock of the clock card lags the output clock of the counterpart clock card, and outputs a low level otherwise.

The method may further include: processing, by a phase locked module, the clock of the clock card before the clock of the clock card is inputted into the Direct Digital Synthesizer.

The present invention further provides a clock card including a Direct Digital Synthesizer and a phase detection module in addition to a Central Processing Unit, a phase locked module, an active and standby states control module.

The Direct Digital Synthesizer is adapted for receiving a phase locked clock sent by the phase locked module, and adjusting a phase of the phase locked clock according to a value in a phase register within the Direct Digital Synthesizer and then outputting a clock of the clock card.

The phase detection module is adapted for detecting a phase difference between the clock of the clock card outputted by the Direct Digital Synthesizer and the clock of the counterpart clock card.

The Central Processing Unit is adapted for, depending on a state (i.e., an active state or a standby state) of the counterpart clock card sent by the active and standby states control module, calculating a value for the phase register in the Direct Digital Synthesizer and sending the value to the Direct Digital Synthesizer, if the clock card is in standby state; and controlling the Direct Digital Synthesizer to stop phase adjustment if the clock card is in active state.

The clock card further includes an output control module, which is adapted for receiving the clock of the clock card outputted by the Direct Digital Synthesizer, and outputting the clock of the clock card according to a control command sent by the active and standby states control module, if the clock card is in active state.

The clock card further includes a reference source detection and selection module, which is adapted for performing detection and selection on a plurality of inputted reference clocks from which a reference clock is selected as a reference clock source which is the same as a reference clock source of the counterpart clock card, and outputting the clock reference source to the phase locked module.

In the invention, a phase of a standby clock is adjusted by a Direct Digital Synthesizer (DDS) according to a detection result of an active clock, thereby achieving alignment between phase of active and standby clocks. The accuracy of clock phase alignment between the active and standby clock cards can be improved to the order of ins or even less, which improves the accuracy of clock phase alignment between the active and standby clocks by more than 10 times or 100 times. Therefore, the various technique indexes of the clock, such as phase discontinuity, can be improved greatly. In addition, for a service device (e.g., a switch, a base station controller, etc.) requiring a clock with high accuracy, problems such as a drop-down due to misalignment between clock phases or low accuracy of alignment in a switchover between active and standby clock cards can be eliminated according to the invention, so that reliability of the device is improved greatly.

### BRIEF DESCRIPTIONS OF THE DRAWINGS

FIG. 1 is a schematic diagram showing configuration of a clock card in the prior art;

FIG. 2 is a schematic diagram showing configuration of a clock card according to an embodiment of the invention;

FIG. 3 is a functional block diagram of a DDS in the clock card shown in FIG. 2;

FIG. 4 is a schematic diagram showing a phase detection module in the clock card shown in FIG. 2;

FIG. 5 is a flow chart of the method for clock phase alignment between active and standby clock cards according to an embodiment of the invention.

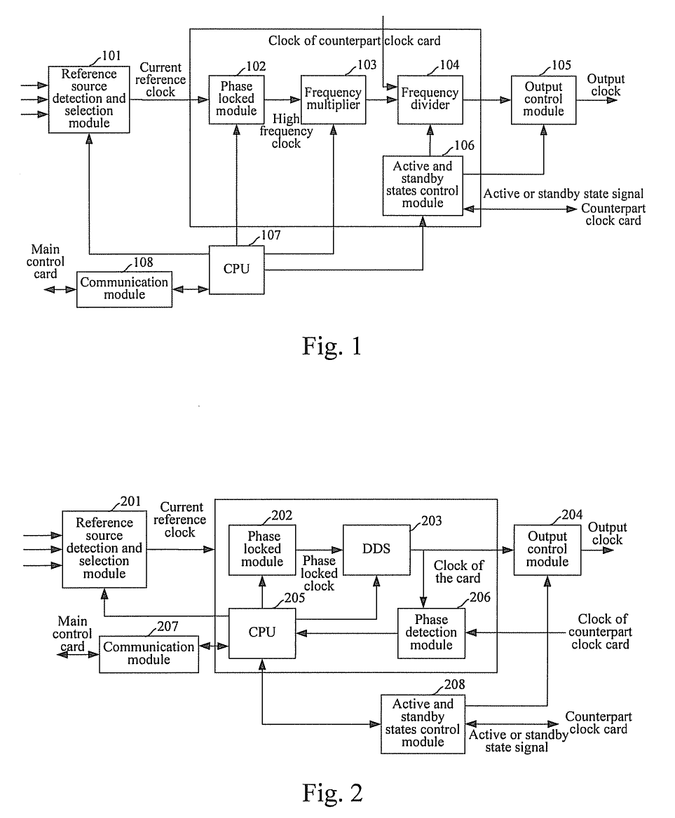

### DETAILED DESCRIPTIONS OF THE EMBODIMENTS

To facilitate understanding and implementation of the invention by the ordinary skilled in the art, embodiments of the invention will be described now with reference to the accompanying drawings.

In the apparatus and the method for clock phase alignment between active and standby clock cards and the clock card provided in the invention, a Direct Digital Synthesizer is used to adjust the phase of the standby clock according to a detection result of the active clock, thereby achieving the alignment between the phases of active and standby clocks.

With reference to FIG. 2, a schematic diagram of configuration of the clock card according to the embodiment of the invention is shown. The clock card includes a DDS 203 and a phase detection module 206, in addition to a reference source detection and selection module 201, a phase locked module 202 for performing phase lock on the selected clock reference source, an output control module 204, an active and standby states control module 208, a CPU 205 and a communication module 207 for communicating with an main control card of the device.

Under the control of the CPU 205, the reference source detection and selection module 201 performs detection on and selection from multiple inputted reference clocks, and picks up and outputs a clock reference source same as that for the counterpart clock card to the phase locked module 202, where the counterpart clock card refers to another clock card having a backup relationship with the clock card.

A clock reference source same as that for the counterpart clock card is selected by the reference source detection and selection module 201, so as to ensure that frequencies of clocks outputted from the active and standby clock cards respectively are consistent with each other.

Under the control of the CPU 205, the phase locked module 202 receives a reference clock source outputted from the reference source detection and selection module 201, performs phase lock on the reference clock source, and outputs the phase locked clock to the DDS 203. The same inputted reference clock is selected by the reference source detection and selection modules 201 of the active and standby clock cards, phase locked clocks having the substantially same frequencies can therefore be obtained through performing phase lock on the reference clock by the respective phase locked modules 203.

The DDS 203 is used to adjust the phase of the clock card. The DDS such as the AD7008 and the AD9852 has the function of phase modulation. The DDS 203 receives the phase locked clock from the phase locked module 202, adjusts the phase of the phase locked clock according to a value in the phase register sent by the CPU 205, and outputs the phase adjusted clock to the output control module 204. Also, the phase adjusted clock is outputted to the phase detection module 206.

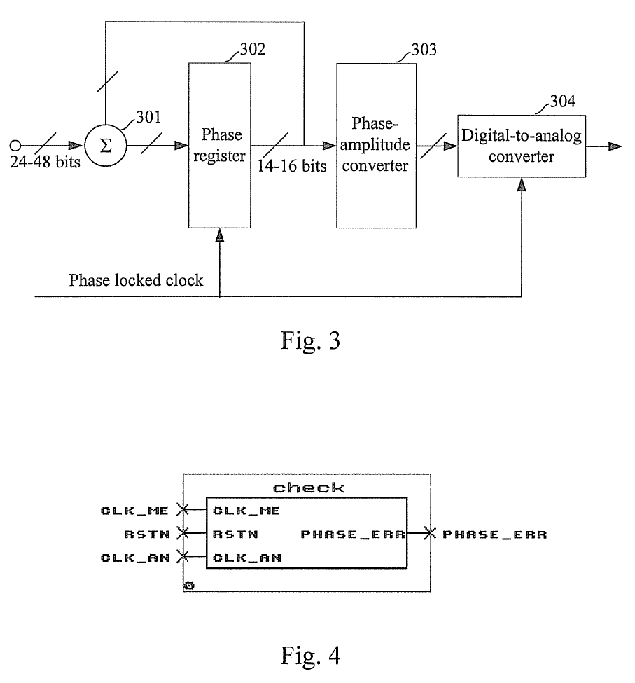

With reference to FIG. 3, the configuration of the DDS 203 is shown. FIG. 3 is a functional block diagram of the DDS in the clock card as shown in FIG. 2. The DDS 203 according to the embodiment is conventional DDS means, and is connected to the CPU 205 via a data bus and an address bus. Specifically, the DDS 203 includes an accumulator 301, a phase register 302, a phase-amplitude converter 303 and a digital-to-analog converter 304.

The DDS is adapted for adjusting both a frequency and a phase. Here, the 24 or 48 bits of data is stored in a frequency register (not shown in FIG. 3), and is used for determining an output frequency; while the 14 or 16 bits of data is stored in a phase register 302 and is used for determining an output phase.

The CPU 205 outputs the fixed 24 or 48 bits of data to the accumulator 301, and writes the 14 or 16 bits of data for determining the output phase into the phase register 302. The accumulator 301 adds the 24 or 48 bits of data to the 14 or 16 bits of data, and outputs an accumulated value to the phase register 302. Based on the accumulated value and the received phase locked clock, the phase register 302 generates a phase parameter, which is sent to the phase-amplitude converter 303. Through conversion, the phase-amplitude converter 303 generates an amplitude parameter, which is sent to the digital-to-analog converter 304. Based on the amplitude parameter and the received phase locked clock, the digital-to-analog converter 304 generates a phase adjusted clock, which is sent to the output control module 204.

In this way, the value in the phase register 302 can be changed with a different value, i.e., the 14 or 16 bits of data, which is sent by the CPU 205, thereby directly adjusting the phase of an output signal from the DDS, without modifying the value in the frequency register of the DDS, in other words, the output phase can be adjusted directly without modifying the output frequency.

The phase detection module 206, which may be implemented by logic devices, is used for detecting whether the clock phase of the clock card leads or lags that of the counterpart clock card. The phase detection module 206 receives a clock outputted from the DDS 203 and a clock from the counterpart clock card, compares phases of these two clocks, and outputs a phase detection result to the CPU 205.

With reference to FIG. 4, a schematic diagram illustrating the phase detection module in the clock card according to the embodiment of the invention as shown in FIG. 2 is shown, where RSTN denotes a reset terminal, CLK_ME denotes an output clock of the clock card, CLK_AN denotes a clock outputted from the counterpart clock card, and PHASE_ERR denotes a phase detection result, with “1” indicating a phase lag and “0” indicating a phase lead. The implementation of the phase detection module includes: detecting whether the clock signal from the counterpart clock card is at a high level or a low level upon arrival of a rising edge of the clock of the clock card; where the high level indicates a phase lag, and the low level indicates a phase lead.

As shown in FIG. 2, depending on a control signal outputted from the active and standby states control module 208, the output control module 204 outputs or does not output the clock signal received from the DDS 203.

The active and standby states control module 208 receives, under the control of the CPU 205, an active or standby state signal sent by the counterpart clock card. If the counterpart clock card is at standby state, in other words, the clock card is at active state, the active and standby states control module 208 sends to the output control module 204 a control signal for outputting a clock; and if the clock card is at standby state, the active and standby states control module 208 sends to the output control module 204 a control signal for stop outputting a clock, and sends the state (i.e., an active state or a standby state) of the counterpart clock card to the CPU 205.

Depending on the state (i.e., an active state or a standby state) of the counterpart clock card sent by the active and standby states control module 208, the CPU 205 controls the DDS 203 to carry out phase adjustment if the counterpart clock card is at active state, i.e., if the clock card is at standby state; and controls the DDS 203 to stop phase adjustment if the clock card is at active state. Specifically, if the clock card is at standby state, according to a result detected by the phase detection module 206, i.e., whether the standby clock leads or lags the active clock, the CPU 205 determines the direction of the phase adjustment by the DDS, calculates and sends to the phase register of the DDS 203 the information of the desired adjusted phase, i.e., the 14 or 16 bits data.

It can be seen from the present embodiment that the phase locked module 202, the DDS 203, the CPU 205 and the phase detection module 206 construct an apparatus for clock phase alignment between the active and standby clock cards. Here, the phase locked module 202 carries out preliminary adjustment on the clock of the clock card according to the reference clock, and may be omitted in implementing the phase alignment.

The communication module 207 as shown in FIG. 2 is same as that in the prior art. Under the control of the CPU 205, the communication module 207 is mainly adapted for mutual communication with a main control card of the device provided with the clock card, and the communication relates to data configuration, state querying, alarm reporting, etc.

Hereinafter, the method for clock phase alignment between active and standby clock cards will be described.

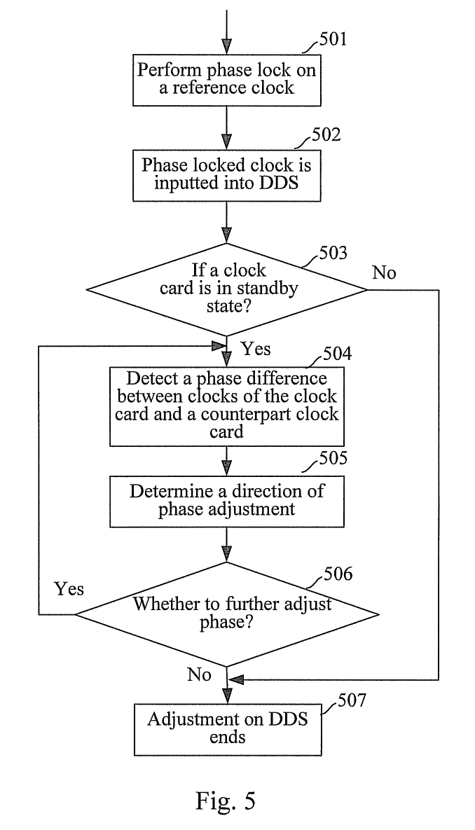

With reference to FIG. 5, a flow chart of the method for clock phase alignment between active and standby clock cards according to an embodiment of the invention is shown. The process includes the following:

At step 501, the phase locked module carries out preliminary adjustment on output clocks of clock cards, so that both the active and standby clock cards after the process of phase lock are consistent in frequency.

At step 502, the phase locked clock is inputted to the DDS.

At step 503, whether the clock card is at standby state is determined; if the clock card is at standby state, the process proceeds to step 504, otherwise, the process proceeds to step 507.

At this step, whether the clock card is at standby state may be determined with the state (i.e., the active state or the standby state) of the counterpart clock card sent by the active and standby states control module; in this case, if the counterpart clock card is at active state, the clock card is at standby state.

At step 504, if the clock card is at standby state, the phase detection module detects a phase difference between respective clocks (having the same frequencies) of the clock card and the counterpart clock card, i.e., to detect whether the clock of the clock card leads or lags that of the counterpart clock card, then step 505 is carried out; if the clock card is at active state, step 504 is not carried out, in other words, the DDS is not adjusted.

At step 505, a direction of phase adjustment is determined according to the phase difference detected by the phase detection module.

If the phase detection module detects that the phase of the clock of the clock card currently leads that of the active clock, the direction of phase adjustment is determined as backward; in contrast, if the phase of the clock from the clock card currently lags that of the active clock, the direction of phase adjustment is determined as forward.

At step 505, information of the desired adjusted phase, i.e., the 14 or 16 bits of data, is calculated according to the determined direction of phase adjustment and the predefined step size, and sent to the phase register of the DDS.

If the direction of phase adjustment is determined as forward, the information of the desired adjusted phase can be obtained by subtracting the predefined step size from the current value of phase in the phase register; if the direction of phase adjustment is determined as backward, the information of the desired adjusted phase can be obtained by adding the predefined step size to the current value of phase in the phase register.

The accuracy of clock phase alignment between active and standby clock cards depends on the number of bits in the phase register of the DDS and the frequency of the output clock from the DDS. The alignment accuracy may be described as 1/(fout*2^{N}), where, fout denotes the frequency of the output clock from the DDS, and N denotes the number of bits in the phase register of the DDS; this alignment accuracy is the highest theoretically-achievable accuracy and the minimum theoretically-achievable step size for adjustment. For example, if the frequency of the clock outputted from the DDS is 16.384 MHz, and the number of bits in the phase register of the DDS is 14, then the achievable minimum step size for adjustment is 1/(16.384*10⁶)/(2¹⁴)=0.0038 ns; and if the frequency of output clock is 2.048 MHz, then the minimum step size for adjustment is 0.03 ns.

At step 505, the DDS adjusts the clock outputting of the clock card according to the value in the phase register, so that the phase of the clock of the standby clock card is aligned to that of the output clock of the active clock card.

At step 506, it is determined whether to further adjust the phase. If further phase adjustment is needed, the process returns to step 504; otherwise, adjustment on the DDS is ended at step 507.

By recording the times for phase lead and phase lag, the CPU calculates, according to the recorded times, probability of outputting a high level or a low level and a ratio of phase lead to phase lag, then adjusts the step size according to the calculated probability, and determines whether the phase needs further adjustment according to the ratio of phase lead to phase lag.

In practice, for fast and accurate clock phase alignment between active and standby clock cards, depending on the read phase errors, different step sizes may be used in adjusting the phase register of the DDS. In the case where a phase lags all the time, for example, high levels are found for 7 or more times upon 10 times of detection on the output of the phase detection module, in other words, the probability of outputting a high level by the phase detection module is approximately 1, or in the case where a phase leads all the time, for example, low levels are found for 7 or more times upon 10 times of detection on the output of the phase detection module, in other words, the probability of outputting a low level by the phase detection module is approximately 1, then forward or backward adjustment is carried out with a larger step size for adjustment, such as 10 times of the minimum step size. In the case where a phase sometimes leads, and sometimes lags, for example, high levels are found for about 6 or 4 times upon 10 times of detection on the output of the phase detection module, in other words, the probability of outputting a high level by the phase detection module is approximately 0.5, at this point, it is indicated that phases are substantially aligned to each other, and the step size for adjustment should be reduced, for example, the minimum step size is to be used. In the case where the ratio of phase lead to phase lag is approximately 50%, for example, the ratio is between 43% and 67%, then the CPU determines that the phases are aligned to each other, and no further adjustment on the DDS is needed, in this case, the phase difference between respective output clocks of the clock card and the counterpart clock card is continuously monitored, when the ratio of phase lead to phase lag that is calculated by the CPU is higher or lower than 50%, for example, the ratio is lower than 43% or higher than 67%, subsequent phase adjustment is carried out.

According to the invention, through the processes of phase lock and of alignment between active and standby clocks, it is ensured that the frequency and phase of resulting clock outputted from the active clock card are consistent with those of resulting clock outputted from the standby clock; furthermore, the accuracy of clock phase alignment between the active and standby clock cards can be improved to the order of Ins or even less, which improves the accuracy of clock phase alignment between the active and standby clocks by more than 10 times or 100 times. Therefore, the various technique indexes of the clock, such as phase discontinuity, can be improved greatly. In addition, for a service device (e.g., a switch, a base station controller, etc.) requiring a clock with high accuracy, problems such as a drop-down due to misalignment between clock phases or low accuracy of alignment in a switchover between active and standby clock cards can be eliminated according to the invention, so that reliability of the device is improved greatly.

The above disclosure is merely embodiments of the invention. It is apparent to those skilled in the art that various modifications and variations can be made to the invention without departing the spirit thereof, and all the modifications and variations are intended to be within the scope of the invention defined by the claims below.

What is claimed is:

1. An apparatus for clock phase alignment between active and standby clock cards, comprising:
a Direct Digital Synthesizer (DDS) adapted for adjusting a phase of an output clock of a clock card according to a value in a phase register within the Direct Digital Synthesizer;
a phase detection module adapted for detecting a phase difference between the phase adjusted output clock of the clock card and an output clock of a counterpart clock card; and
a Central Processing Unit adapted for calculating the value for the phase register within the Direct Digital Synthesizer according to the phase difference detected by the phase detection module, and sending the value to the Direct Digital Synthesizer.

2. The apparatus for clock phase alignment between active and standby clock cards according to claim 1, further comprising: a phase locked module adapted for phase lock adjustment according to a reference clock of clock card, and outputting a phase locked clock to the Direct Digital Synthesizer.

3. The apparatus for clock phase alignment between active and standby clock cards according to claim 2, wherein the Direct Digital Synthesizer comprises the phase register, a phase-amplitude converter and a digital-to-analog converter;
the Central Processing Unit is adapted to write into the phase register the calculated value for the phase register within the Direct Digital Synthesizer;
the phase register is adapted to generate a phase parameter according to the received phase locked clock, and sends the phase parameter to the phase-amplitude converter; and
the phase-amplitude converter is adapted to generate an amplitude parameter through conversion, and sends the amplitude parameter to the digital-to-analog converter; the digital-to-analog converter is adapted to generate a phase adjusted clock output according to the amplitude parameter and the received phase locked clock.

4. The apparatus for clock phase alignment between active and standby clock cards according to claim 1, wherein the Central Processing Unit is connected to the Direct Digital Synthesizer via a data bus and an address bus.

5. A method for clock phase alignment between active and standby clock cards, comprising:
if a clock card is in standby state, performing the steps of:
A. detecting a phase difference between an output clock of the clock card and an output clock of a counterpart clock card; and
B. adjusting, by a Direct Digital Synthesizer, a phase of the output clock of the clock card to be aligned to a phase of the output clock of the counterpart clock card, according to the detected phase difference.

6. The method for clock phase alignment between active and standby clock cards according to claim 5, wherein the step B comprises:
B1. calculating a value for a phase register of the Direct Digital Synthesizer according to the detected phase difference, and sending the value to the Direct Digital Synthesizer; and
B2. adjusting, by the Direct Digital Synthesizer, the phase of the output clock of the clock card to be aligned to the phase of the output clock of the counterpart clock card, according to the value in the phase register.

7. The method for clock phase alignment between active and standby clock cards according to claim 6, wherein the step A comprises:
detecting whether the output clock of the clock card leads or lags the output clock of the counterpart clock card; and
the step B1 comprises:
determining a direction of phase adjustment according to a detection result from the step A, and determining that the value in the phase register of the Direct Digital Synthesizer is an original value in the phase register plus or minus a predefined step size.

8. The method for clock phase alignment between active and standby clock cards according to claim 7, further comprising:
determining whether further phase adjustment is needed; if the further phase adjustment is needed, returning to step A; otherwise, ending the adjustment.

9. The method for clock phase alignment between active and standby clock cards according to claim 8, wherein the determining whether further phase adjustment is needed comprises:
recording times for performing forward phase adjustment or backward phase adjustment; if a ratio of the times for one of the forward phase adjustment and the backward phase adjustment to the times for the other of the forward phase adjustment and the backward phase adjustment is approximately 50%, then no further phase adjustment is needed.

10. The method for clock phase alignment between active and standby clock cards according to claim 8, wherein the determining whether further phase adjustment is needed comprises:
recording times for performing forward phase adjustment or backward phase adjustment; if a ratio of the times for one of the forward phase adjustment and the backward phase adjustment to the times for the other of the forward phase adjustment and the backward phase adjustment is between 43% and 67%, then no further phase adjustment is needed.

11. The method for clock phase alignment between active and standby clock cards according to claim 9, wherein the step B1 further comprises:
when a ratio of the times for one of the forward phase adjustment and the backward phase adjustment to times for the other of the forward phase adjustment and the backward phase adjustment is higher than a predefined value, a step size for the one of the forward phase adjustment and the backward phase adjustment is adjusted to be integral times of the predefined step size.

12. The method for clock phase alignment between active and standby clock cards according to claim 10, wherein the step B1 further comprises:
when a ratio of the times for one of the forward phase adjustment and the backward phase adjustment to times for the other of the forward phase adjustment and the backward phase adjustment is higher than a predefined value, a step size for the one of the forward phase adjustment and the backward phase adjustment is adjusted to be integral times of the predefined step size.

13. The method for clock phase alignment between active and standby clock cards according to claim 5, wherein the phase difference between the output clock of the clock card and the output clock of the counterpart clock card is detected by a phase detection module, the phase detection module outputs a high level if the output clock of the clock card lags the output clock of the counterpart clock card, and outputs a low level otherwise.

14. The method for clock phase alignment between active and standby clock cards according to claim 5, further comprising:
processing, by a phase locked module, a clock of the clock card before the clock of the clock card is inputted into the Direct Digital Synthesizer.

15. A clock card having a Central Processing Unit, a phase locked module, an active and standby states control module, further comprising a Direct Digital Synthesizer and a phase detection module, wherein:
the Direct Digital Synthesizer is adapted for receiving a phase locked clock sent by the phase locked module, and adjusting a phase of the phase locked clock according to a value in a phase register within the Direct Digital Synthesizer and then outputting a clock of a clock card;
the phase detection module is adapted for detecting a phase difference between the clock of the clock card outputted by the Direct Digital Synthesizer and a clock of a counterpart clock card; and
the Central Processing Unit is adapted for, depending on a state of the counterpart clock card sent by an active and standby states control module, calculating the value for the phase register in the Direct Digital Synthesizer and sending the value to the Direct Digital Synthesizer if the clock card is in standby state; and controlling the Direct Digital Synthesizer to stop phase adjustment if the clock card is in active state.

16. The clock card according to claim 15, further comprising:
an output control module adapted for receiving the clock of the clock card outputted by the Direct Digital Synthesizer, and outputting the clock of the clock card according to a control command sent by the active and standby states control module in the case that the clock card is in active state.

17. The clock card according to claim 15, further comprising:
a reference source detection and selection module adapted for performing detection and selection on a plurality of inputted reference clocks from which a reference clock is selected as a reference clock source which is the same as a reference clock source of the counterpart clock card, and outputting the clock reference source to the phase locked module.
